(19) United States
(12) Patent Application Publication
(10) Pub. No.: US 2024/0405714 A1
(43) Pub. Date: Dec. 5, 2024

(54) INFORMATION PROCESSING APPARATUS, INFORMATION PROCESSING METHOD, SEMICONDUCTOR DEVICE, AND POWER CONVERSION DEVICE

(71) Applicant: Renesas Electronics Corporation, Tokyo (JP)

(72) Inventor: Hiroyuki KOKUBUN, Tokyo (JP)

(21) Appl. No.: 18/678,803

(22) Filed: May 30, 2024

(30) Foreign Application Priority Data
Jun. 5, 2023 (JP) 2023-092486

(51) Int. Cl. H02P 29/68; H02M 1/32

(52) U.S. Cl. CPC H02P 29/68; H02M 1/327

(57) ABSTRACT

To be able to detect abnormalities more appropriately. An information processing apparatus includes an acquisition circuit and an estimation circuit. It acquires information indicating a temperature transition and a current transition related to a semiconductor element of a power conversion device and an electric motor. And it estimates an anomaly of a specific type in a system based on the acquired information.

### CROSS-REFERENCE TO RELATED APPLICATIONS

The disclosure of Japanese Patent Application No. 2023-092486 filed on Jun. 5, 2023, including the specification, drawings and abstract is incorporated herein by reference in its entirety.

### BACKGROUND

The present disclosure relates to an information processing apparatus, an information processing method, and a power conversion apparatus.

Conventionally, a technique of periodically monitoring an anomaly of a power conversion device (inverter) is known.

There are disclosed techniques listed below.
[Patent Document 1] Japanese Unexamined Patent Application Publication No. 2019-078728

### SUMMARY

In the related art, for example, an anomaly of a power conversion device or an electric motor may not be appropriately detected in some cases. Other objects and novel features will become apparent from the description of this specification and the accompanying drawings.

According to an embodiment of the present disclosure, there is provided an information processing apparatus including: an acquisition unit that acquires information indicating a change in temperature of a semiconductor element of a power conversion device that drives an electric motor; information indicating a change in current input to the electric motor; and an estimation unit that estimates an anomaly of a specific type in at least one of the power conversion device and the electric motor based on the information acquired by the acquisition unit.

Further, according to an embodiment of the present disclosure, there is provided an information processing method in which an information processing apparatus executes processing by acquiring information indicating a change in temperature of a semiconductor element of a power conversion apparatus that drives an electric motor and information indicating a change in current input to the electric motor, and estimating an anomaly of a specific type in at least one of the power conversion apparatus and the electric motor based on the acquired information.

Further, according to an embodiment of the present disclosure, there is provided a power conversion apparatus that drives an electric motor, the power conversion apparatus including: an acquisition unit that acquires information indicating a change in temperature of a semiconductor element of the power conversion apparatus and information indicating a change in current input to the electric motor; and an estimation unit that estimates an anomaly of a specific type in at least one of the power conversion apparatus and the electric motor based on the information acquired by the acquisition unit.

According to one side surface, an anomaly can be detected more appropriately.

### BRIEF DESCRIPTION OF THE DRAWINGS

FIG. 1 is a diagram illustrating an example of a configuration of a drive system according to an embodiment.

FIG. 2 is a diagram illustrating an example of a configuration of an information processing apparatus according to an embodiment.

FIG. 3 is a flowchart illustrating an example of processing performed by an information processing apparatus according to an embodiment.

FIG. 4 is a diagram showing an example of a spectrum when there is an anomaly in the semiconductor element according to the embodiment.

FIG. 5 is a diagram illustrating an example of information recorded in an anomaly coefficient table according to an embodiment.

FIG. 6 is a diagram illustrating an example of a power cycle life (number of power cycles) according to a temperature difference of a semiconductor element 21 according to an embodiment.

FIG. 7 is a diagram illustrating an exemplary anomaly coefficient Fᵢ according to an embodiment.

FIG. 8 is a diagram showing an exemplary frequency Dᵢ of the measured value i according to the embodiment.

FIG. 9 is a diagram showing an example of information recorded in the correlation definition information according to the embodiment.

FIG. 10 is a diagram illustrating an example of information recorded in an anomaly inspection frequency table according to an embodiment.

FIG. 11 is a diagram illustrating an example of a configuration of an information processing apparatus according to an embodiment.

### DETAILED DESCRIPTION

The principles of the present disclosure are described with reference to several exemplary embodiments. It should be understood that these embodiments are set forth for purposes of illustration only and that those skilled in the art will assist in understanding and practicing the disclosure without suggesting limitations on the scope of the disclosure. The disclosure described herein may be implemented in a variety of ways other than those described below.

In the following description and claims, unless otherwise defined, all technical and scientific terms used herein have the same meaning as commonly understood by one of ordinary skill in the art to which this disclosure belongs.

Hereinafter, embodiments of the present disclosure will be described with reference to the drawings.

### Configuration

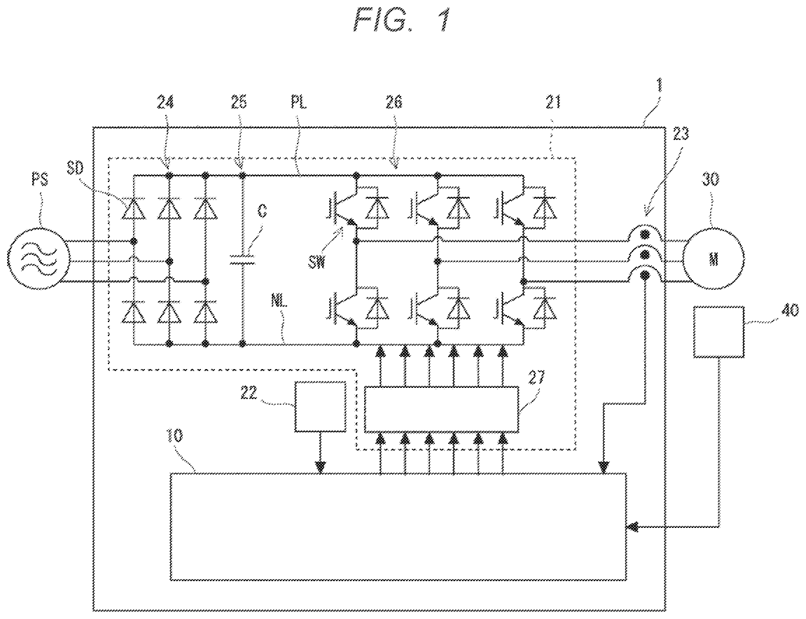

A configuration of the drive system 1 according to the embodiment will be described with reference to FIG. 1. FIG. 1 is a diagram illustrating an example of a configuration of a drive system 1 according to an embodiment. In the example of FIG. 1, the drive system 1 includes a power conversion device 20, an electric motor 30, and a vibration sensor 40.

The electric motor 30 is a machine that converts electrical energy into mechanical energy. The power conversion device 20 is a device that generates an alternating current having a different frequency from a direct current or an alternating current to drive the electric motor 30 at a desired rotational speed or torque.

The vibration sensor 40 is provided in the vicinity of the electric motor 30, and is a sensor that measures vibration in the vicinity of the electric motor 30. The vibration sensor 40 may be, for example, a piezoelectric sensor or a MEMS sensor that detects acceleration. Further, the vibration sensor 40 may be, for example, a laser Doppler sensor that emits laser light and detects a speed based on a frequency change of the reflected laser light. The vibration sensor 40 may be, for example, a capacitive sensor that measures a displacement (change in distance) between the sensor and the measurement object based on a change in capacitance between the sensor and the measurement object. The vibration sensor 40 may estimate the vibration based on, for example, a speed variation value output from a speed sensor that detects a rotation speed or a magnetic pole position attached to the electric motor 30 and a differential value of the position.

In the example of FIG. 1, the power conversion device 20 includes a semiconductor element 21, a temperature sensor 22, a current sensor 23, and an information processing device 10. The semiconductor element 21 includes a rectifier circuit 24, a smoothing circuit 25, an inverter circuit 26, and a gate driving circuit 27. The device 21 may include, for example, a thyristor, a power transistor, a MOS-FET (Metal-Oxide-Semiconductor Field Effect Transistor, an insulated gate bipolar transistor (Insulated-Gate Bipolar Transistor, IGBT), and the like. Further, the semiconductor device 21 may include, for example, a SiC power semiconductor (silicon carbide MOSFET) that consumes less power than IGBT.

The temperature sensor 22 is provided in the vicinity of the semiconductor element 21, and is a sensor that measures the temperature in the vicinity of the semiconductor element 21. The current sensor 23 is a sensor that measures a current input from the power conversion device 20 to the electric motor 30. The current sensor 23 may detect a current of each of the three-phase (three) output lines of the power converter 20, that is, a current of each of the three phases of the electric motor 30. The current sensor 23 may be integrated with the semiconductor element or may be provided in a heat sink portion that cools the semiconductor element. In addition, the current sensor 23 may be a temperature sensor inside a CPU described later or a temperature sensor installed on a substrate.

The information processing apparatus 10 is a computer that controls each unit of the power conversion apparatus 20. The information processing device 10 may be, for example, a microcontroller in which CPU (Central Processing Unit), RAM (Random access memory), ROM (Read only memory), I/O(Input/Output) and the like are implemented as one integrated circuit (IC, Integrated Circuit).

The rectifier 24 is configured to rectify three-phase AC power inputted from the power supply PS and to be capable of outputting DC power. The rectifier circuit 24 can output DC power to the smoothing circuit 25 through the positive line PL and the negative line NL while the positive and negative output terminals are connected to one ends of the positive line PL and the negative line NL, respectively. The rectifier circuit 24 may be, for example, a bridge-type full-wave rectifier circuit including six semiconductor diode SD and in which three series-connected bodies of two semiconductor diode SD constituting the upper and lower arms are connected in parallel.

The smoothing circuit 25 suppresses and smoothes the pulsation of the DC power output from the rectifier circuit 24 and the DC power regenerated from the inverter circuit 26. The smoothing circuit 25 includes, for example, a smoothing capacitor C. The smoothing capacitor C may be provided in a path connecting the positive line PL and the negative line NL in parallel with the rectifier circuit 24 and the inverter circuit 26. The smoothing capacitor C smoothes the DC power output from the rectifier circuit 24 and the DC power output (regeneration) from the inverter circuit 26 while repeating charging and discharging as appropriate. The smoothing capacitor C may be one. In addition, a plurality of smoothing capacitors C may be arranged, and a plurality of smoothing capacitors C may be connected in parallel between the positive line PL and the negative line NL, or may be connected in series. Further, the plurality of smoothing capacitors C may be configured such that a series-connected body of two or more smoothing capacitors is connected in parallel between the positive line PL and the negative line NL.

The smoothing circuit 25 may include, for example, a reactor. The reactor may be provided in a positive-line PL between the circuit 24 and the smoothing capacitor C (specifically, a branch point between the rectifier and a path in which the smoothing capacitor C is disposed). The reactor smoothes the DC power output from the rectifier circuit 24 and the DC power output (regeneration) from the inverter circuit 26 while generating a voltage to prevent a change in the current as appropriate.

In the inverter circuit 26, the positive and negative inputs of the inverter circuit 26 are connected to the other ends of the positive line PL and the negative line NL. The inverter circuit 26 converts the DC power supplied from the smoothing circuit 25 into three-phase AC power (for example, U-phase, V-phase, and W-phase) having a predetermined frequency or a predetermined voltage by the switching operation of the semiconductor-switching SW, and outputs the three-phase AC power to the electric motor 30. The semiconductor-switching SW may be, for example, a IGBT (Insulated Gate Bipolar Transistor (Si) or a MOSFET (Metal-Oxide-Semiconductor Field-Effect Transistor). The semiconductor switching SW may be, for example, a semiconductor device using a wide-bandgap semiconductor such as silicon carbide (SiC) or gallium nitride (GaN).

The inverter circuit 26 includes, for example, six semiconductor switch SW, and includes a bridge circuit in which a series connection (switch leg) of two semiconductor switch SW constituting the upper and lower arms is connected in three sets in parallel between the positive line PL and the negative line NL. The inverter circuit 26 may output three-phase AC power through three output lines drawn from the connection points of the three sets of upper and lower arms. Further, the six semiconductor-switching SW may be connected in parallel with each other. Under the control of the control circuit 80, the gate drive circuit 27 outputs a drive signal for switching (ON/OFF) the six semiconductor switch SW of the inverter circuit 26 to the gate terminals of the six semiconductor switch SW.

### <Configuration of Information Processing Apparatus 10>

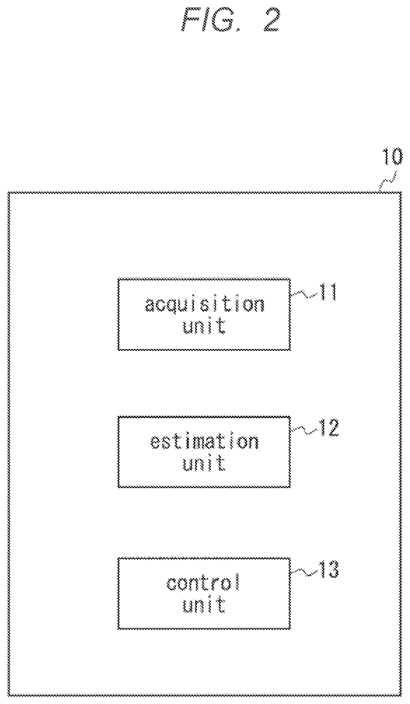

Next, a configuration of the information processing apparatus 10 according to the embodiment will be described with reference to FIG. 2. FIG. 2 is a diagram illustrating an example of a configuration of the information processing apparatus 10 according to the embodiment. The information processing apparatus 10 includes an acquisition unit 11, an estimation unit 12, and a control unit 13. These units may be realized by cooperation of one or more programs installed in the information processing apparatus 10 and hardware including circuits, such as a processor and a memory of the information processing apparatus 10.

The acquisition unit 11 acquires, for example, data measured by the temperature sensor 22, the current sensor 23, and the vibration sensor 40. The estimation unit 12 estimates an anomaly of a specific type in at least one of the power conversion device 20 and the electric motor 30 based on the information acquired by the acquisition unit 11. The control unit 13 performs control (output) according to the anomaly of the specific type estimated by the estimation unit 12.

The specific type (type of anomaly) may include, for example, at least one of damage to the bearing of the electric motor 30 (for example, damage to the inner ring), wear of the bearing of the electric motor 30, overload of the electric motor 30, overload of the electric power conversion device 20, dielectric breakdown of the electric motor 30, dielectric breakdown of the electric power conversion device 20, imbalance (unbalance) of the electric motor 30, misalignment of the electric motor 30, and load anomaly of the electric motor 30.

The overload of the electric motor 30 is that, for example, when a relatively large load is applied during the rotation of the electric motor 30 or the like, a relatively large electric power is input to the electric motor 30 from the power conversion device 20.

The overload of the electric motor 30, for example, increases the temperature of the electric motor 30 to promote wear of the bearing, which may lead to a failure of the bearing.

The imbalance of the electric motor 30 is that, for example, the centrifugal force at the time of rotation is not balanced as a whole because the masses of the mechanical parts, structures, and shapes connected to the rotating shaft are not uniformly distributed. The imbalance of the motor 30 may, for example, promote wear of the bearing due to the direction displacement of the shaft, leading to failure of the bearing.

The misalignment of the electric motor 30 is, for example, that the shaft rotates in a deflected state due to an attachment error of the load shaft to the shaft or the like. Since the shaft of the shaft rotates while being swung outward, wear of the bearing is promoted, which may lead to failure of the bearing.

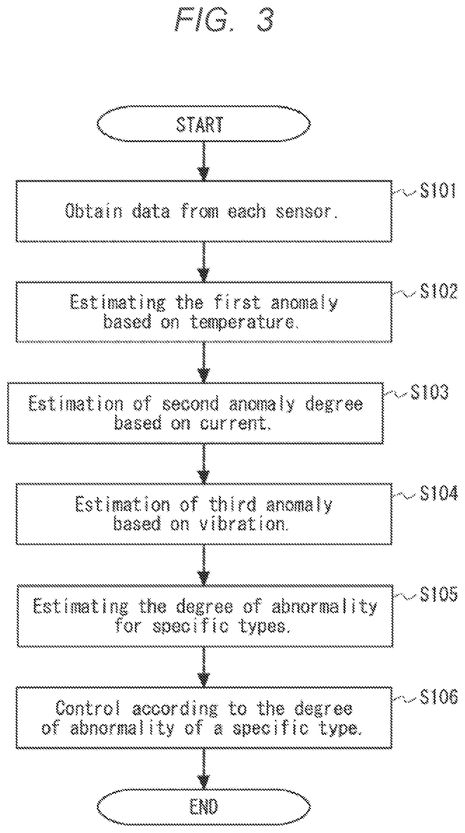

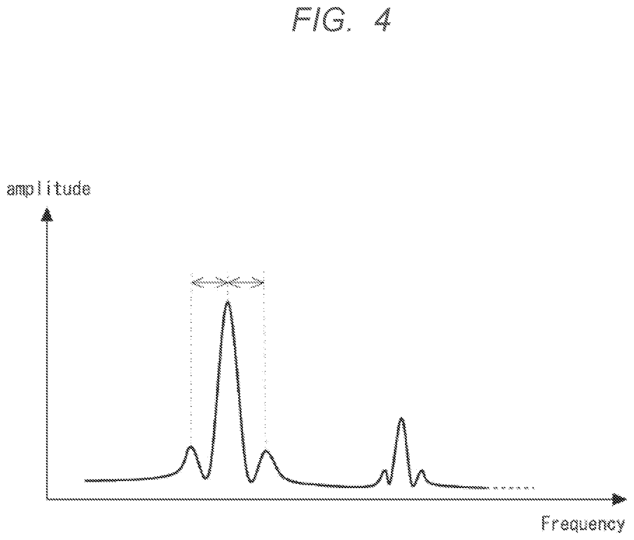

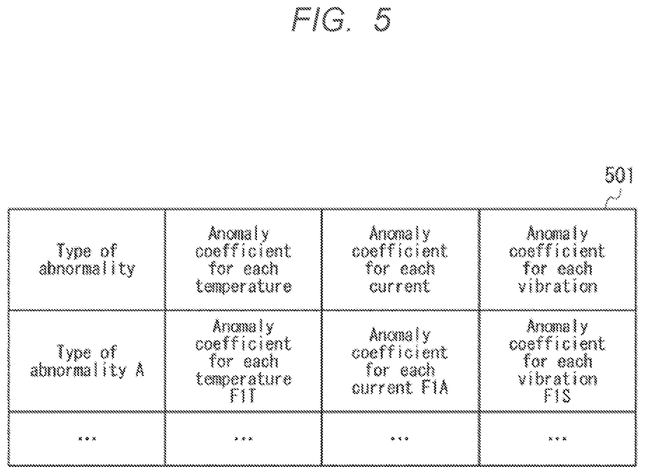

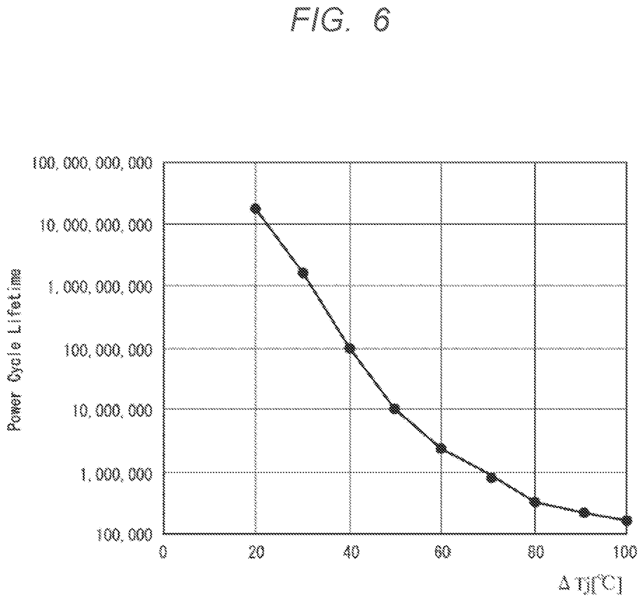

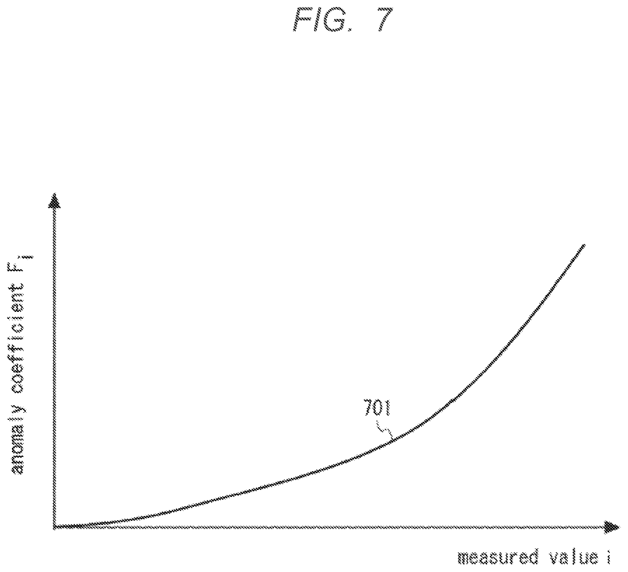

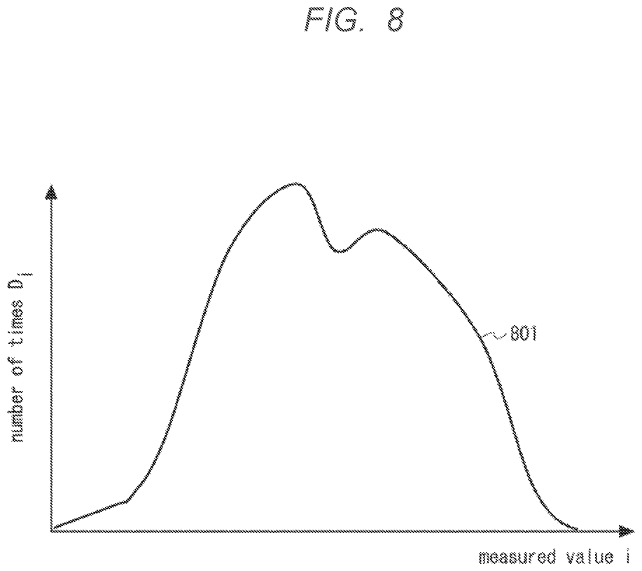

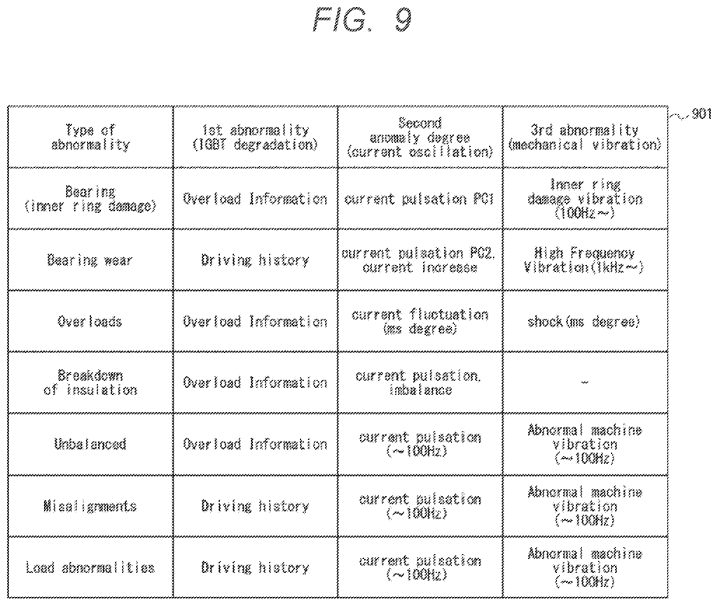

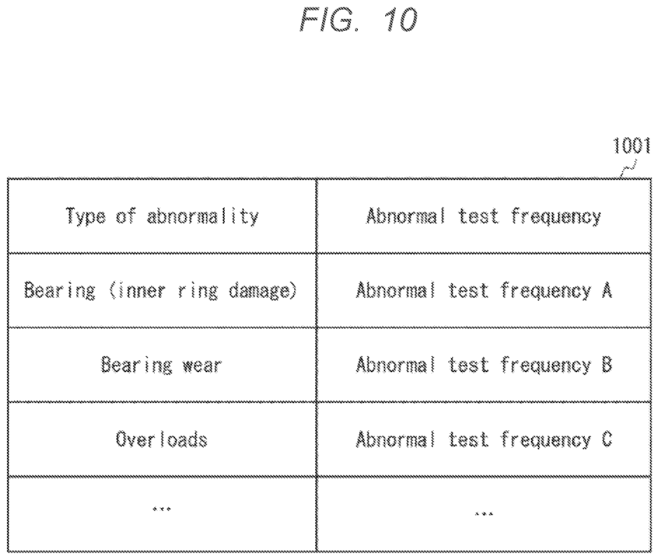

Processing of the information processing apparatus 10 Next, an example of processing of the information processing apparatus 10 according to the embodiment will be described with reference to FIGS. 3 to 7. FIG. 3 is a flowchart illustrating an example of processing performed by the information processing apparatus 10 according to the embodiment. FIG. 4 is a diagram illustrating an example of a spectrum in a case where there is an anomaly in the semiconductor element 21 according to the embodiment. FIG. 5 is a diagram illustrating an example of information recorded in the anomaly coefficient table 501 according to the embodiment. FIG. 6 is a diagram illustrating an example of the power cycle life (the number of times of power cycles) according to the temperature difference of the semiconductor element 21 according to the embodiment. FIG. 7 is a diagram illustrating an exemplary anomaly coefficient Fᵢ701 according to the embodiment. FIG. 8 is a diagram illustrating an exemplary frequency D₁801 of respective measured values i according to the embodiment. FIG. 9 is a diagram illustrating an example of information recorded in the correlation definition information 901 according to the embodiment. FIG. 10 is a diagram illustrating an example of information recorded in the anomaly inspection frequency table 1001 according to the embodiment.

Note that the processing of FIG. 3 may be executed at different timings for each type of anomaly to be estimated (diagnosed). In this case, for example, the anomaly of the first type may be estimated in the first cycle (for example, every 20 minutes), and the anomaly of the second type may be estimated in the second cycle (for example, every 5 minutes). In the following, an example in which data measured by three sensors of the temperature sensor 22, the current sensor 23, and the vibration sensor 40 is used will be described, but the information processing apparatus 10 may perform estimation using data measured by at least two sensors.

In step S101, the acquiring unit 11 acquires information indicating a transition in the first period (for example, the last 20 minutes) of the temperature in the semiconductor device 21 of the power converter 20 that drives the electric motor 30, information indicating a transition in the first period of the current inputted to the electric motor 30, and information indicating a transition in the first period of the oscillation in the electric motor 30.

Here, the acquisition unit 11 may acquire, for example, data measured at each time point by the temperature sensor 22, the current sensor 23, and the vibration sensor 40. In this case, the acquisition unit 11 may record data measured at each time point by the temperature sensor 22, the current sensor 23, and the vibration sensor 40 in the storage device, for example. FIG. 4 shows an example of the spectrum in the frequency domain generated in the current input to the electric motor 30 when there is an anomaly in the semiconductor element 21. In the example of FIG. 4, it is shown that an abnormal spectrum called a sideband wave increases in accordance with the rotation speed of the electric motor 30.

When acquiring vibration data based on the vibration sensor 40, the acquiring unit 11 may perform preprocessing using an envelope process used to remove the metallic resonance frequency of the housing and obtain a desired vibration component, and FFT (Fast Fourier Transform). In addition, when the anomaly vibration is acquired based on the current detected by the current sensor 23, the acquisition unit 11 may perform spectrum analysis on a minute current change by FFT. Then, the acquisition unit 11 may use the sideband wave by the mechanical angle and the integer multiple frequency of the electrical angle as search points. Then, the acquisition unit 11 may normalize the value of the spectrum according to the rotation speed of the electric motor 30. Since the spectrum and the range of the frequency at which the abnormal sign occurs differ depending on the type of the anomaly described later, the condition of the range of the frequency and the threshold regarded as the anomaly for each anomaly type may be held in advance in the anomaly coefficient table 501 as the anomaly coefficient of each current and the anomaly coefficient of each vibration.

Subsequently, the estimation unit 12 estimates the first anomaly of the specific type in the first period based on the transition of the temperature in the semiconductor element 21 in the first period and the information indicating the anomaly likeness of the specific type corresponding to the respective temperatures of the semiconductor element 21 (step S102). Here, the estimation unit 12 may estimate the first anomaly on the basis of, for example, a temperature change of the semiconductor element 21 and an anomaly coefficient of each temperature corresponding to a specific anomaly type registered in the anomaly coefficient table 501 of FIG. 5. The anomaly coefficient of each temperature according to the specific anomaly type may be, for example, a value set based on the power cycle life curve (lifetime characteristic data) of the semiconductor element 21 illustrated in FIG. 6. The power cycle life curve quantitatively represents damage such as peeling of wire bonding caused by thermal fatigue of the metal from temperature change in the semiconductor element and cracking of the solder of the chip and the base substrate. In the example of FIG. 5, the anomaly coefficient table 501 records the anomaly coefficient of each temperature, the anomaly coefficient of each current, and the anomaly coefficient of each vibration in association with the type of anomaly. The data of the anomaly coefficient table 501 may be created based on, for example, past experience, and may be set in advance by an administrator or the like of the information processing apparatus 10. Numerical data commonly used in appliance lifetime designs may be used, such as the power cycle lifetime curves of the components described above. In this case, for example, the anomaly coefficient Fᵢ of each temperature may be determined based on the power-cycle lifetime defined as the lifetime for each measured value i of the temperature change in the semiconductor device 21 according to the specific type.

The vertical axis of FIG. 6 shows the power cycle life (number of power cycles) on a logarithmic scale. In the example of FIG. 6, the power cycle life of the semiconductor element 21 becomes relatively long (larger) when the cycle temperature difference ΔTj is relatively small, and becomes exponentially smaller as the cycle temperature difference ΔTj increases.

Here, the estimation unit 12 may refer to the anomaly coefficient table 501 to acquire the anomaly coefficient Fᵢ for the respective measured values i of the temperature change in the semiconductor device 21 according to the particular type. Then, the estimation unit 12 may calculate the sum of the values obtained by multiplying the frequency Dᵢ by the anomaly factor Fᵢ for the respective measured values i as the value R of the first anomaly in the first period, as in the following Expression (1). Note that each measurement value i may be, for example, a predetermined lower limit value (for example, 10° C. in the case of a temperature change) may be set to 0, and a predetermined upper limit value (for example, 100° C. in the case of a temperature change) may be set to n. The anomalousness coefficient Fᵢ is a relative coefficient corresponding to the anomalousness of a particular type due to the respective measured values i. In this case, the anomaly coefficient Fᵢ may be calculated, for example, from the coefficient of the detected gain (margin) and the inverse of the number of times of power cycles at the point corresponding to the corresponding temperature change in the power cycle life curve. Note that the detection gain may be, for example, a value for setting an adjustment value in accordance with an application (for example, an application for vertical conveyance of a severe crane or the like) or a cooling capacity of a place where the power conversion device is placed. The frequency Dᵢ of each measured value i is the number of times that the measured value i was at each time point in the first time period. For example, the frequency Dₖ is 10 when the number of times measured to be the specified temperature change k is 10 at the respective time points in the first time interval. According to Equation (1), the closer R is to the maximum value (e.g., 1.0), the closer the quantitative indicator that the lifetime of the semiconductor device is obtained.

$$\begin{matrix}[ Equation 1 ] & \\ R = {\sum }_{i = 0}^{n} {F}_{i} \times {D}_{i} & ( 1 )\end{matrix}$$

FIG. 7 shows an exemplary anomaly coefficient Fᵢ701 of the respective measured values i. In FIG. 7, the horizontal axis represents the measured value i, and the vertical axis represents the value of the anomaly coefficient Fᵢ. FIG. 8 shows an exemplary frequency Dᵢ801 of the respective measured values i. In FIG. 8, the horizontal axis represents the measured value i, and the vertical axis represents the value of the frequency Dᵢ.

Subsequently, the estimation unit 12 estimates the second anomaly of the specific type in the first period on the basis of the transition of the current input to the electric motor 30 in the first period and the information indicating the anomaly likelihood of the specific type of the current input to the electric motor 30 (step S103). Here, the estimation unit 12 may refer to the anomaly coefficient table 501 and acquire an anomaly coefficient with respect to each measured value of the current input to the electric motor 30 according to the specific type or the amount of change in the current. Then, similarly to the step S102, the estimation unit 12 may calculate the sum of the values obtained by multiplying the frequency by the anomaly coefficient for the respective measured values of the current or the variation of the current as the value of the second anomaly factor in the first period.

Subsequently, the estimation unit 12 estimates the third anomaly of the specific type in the first period based on the transition of the vibration in the electric motor 30 in the first period and the information indicating the anomaly likelihood of the specific type corresponding to the vibration in the electric motor 30 (step S104).

Here, the estimation unit 12 may refer to the anomaly coefficient table 501 to acquire the anomaly coefficient of each vibration in the electric motor 30 according to the specific type. Then, similarly to the step S102, the estimation unit 12 may calculate the sum of the values obtained by multiplying the frequency by the anomaly coefficient for the respective measured values of the vibrations as the value of the third anomaly in the first period. Note that each measured value of vibration may be a vibration amount (displacement) or a value of each vibration frequency calculated by a FFT, a tracking filter, a band-pass filter, or the like.

Subsequently, the estimation unit 12 estimates the anomaly of the specified type on the basis of the estimated correlations of the first anomaly, the second anomaly, and the third anomaly (the correlation between the first anomaly and the second anomaly, the correlation between the second anomaly and the third anomaly, and the correlation between the third anomaly and the first anomaly) (step S105). Here, for example, the estimation unit 12 may determine the value of the anomaly of the specific type to be a high value as at least one of the first anomaly, the second anomaly, and the third anomaly increases and as the correlation between the first anomaly, the second anomaly, and the third anomaly increases. Here, the estimation unit 12 may determine the degree of correlation between the first anomaly, the second anomaly, and the third anomaly based on the correlation definition information 901 illustrated in FIG. 9. Note that the data of the correlation definition information 901 illustrated in FIG. 9 may be set (registered) in advance by an administrator (operator) or the like of the information processing apparatus 10.

In the example of FIG. 9, when the correlation between the overload information, the specific current pulsation, and the inner ring damage vibration is equal to or larger than the threshold value, it is determined that the bearing (inner ring damage) is abnormal. The overload information may be, for example, the value of the first anomaly R1 calculated based on the anomaly coefficient Fᵢ calculated from the inverse of the power cycle number at the point corresponding to the temperature change corresponding to the power cycle life curve and the coefficient of the detected gain (margin) according to the above-described Expression (1). The specific current pulsation may be, for example, the second anomaly R2 calculated based on the anomaly coefficient corresponding to the frequency spectrum of each cycle in which the magnitude of the current fluctuates according to the above-described Expression (1). The inner ring damage vibration may be, for example, the third anomaly R3 calculated based on the anomaly coefficient corresponding to the frequency spectrum of the respective periods at a 100 Hz or more at which the magnitude of the vibration varies according to Expression (1) described above.

For example, the estimation unit 12 may determine that the correlation is higher as the tendency and the degree of change of each anomaly (each of the first anomaly, the second anomaly, and the third anomaly) are closer. In this case, the estimation unit 12 may calculate, for example, a value of a difference or a ratio between the value of the first anomaly estimated last time and the value of the first anomaly estimated this time as a value indicating the degree of change of the first anomaly. Further, for example, the estimation unit 12 may calculate the correlation coefficient of the value of each anomaly as the correlation. Note that, for example, the estimation unit 12 may logically determine the degree of each correlation based on one or more decision trees in which weights or priorities are provided for each of the anomalies.

For example, when the current input to the electric motor 30 increases, there is a possibility that it is not abnormal only by moving a relatively heavy object. According to the present disclosure, since an anomaly is estimated based on a correlation between measurement values of a plurality of measurement items, it is possible to more appropriately detect the presence or absence of an anomaly

Subsequently, the control unit 13 performs control (outputting) according to the anomaly of the specific type estimated by the estimation unit 12 (step S106). Here, for example, when the anomaly of the specific type is equal to or greater than the threshold value, the control unit 13 may set the frequency of inspection for the anomaly of the specific type to a relatively high frequency as shown in FIG. 10. In the example of FIG. 10, the anomaly inspection frequency table 1001 records the anomaly inspection frequency in association with the type of anomaly. Thus, for example, even in a case where the time from the start of occurrence of a relatively small amount of anomaly in a component to the progress to a relatively large anomaly is short, the anomaly can be detected more quickly. Therefore, for example, the power conversion device 20 and the electric motor 30 can be stopped before a larger failure occurs.

In addition, for example, when the anomaly of the specific type is less than the threshold value, the control unit 13 may set the frequency of inspection for the anomaly of the specific type to a relatively low frequency. Thus, for example, the processing load for the anomaly inspection can be reduced. For example, it is assumed that the information processing device 10, which is a microcontroller of the power converter 20, performs a process for controlling the electric motor 30 in synchronization with the carrier frequency of PWM (Pulse Width Modulation), and performs a process for abnormal test between the processes. In this case, it is useful to reduce a processing load for abnormal test.

In addition, for example, when the anomaly of the specific type is equal to or greater than the threshold value, the control unit 13 may output information indicating the specific type. Thus, for example, it is possible to realize predictive maintenance that prompts a maintenance staff to perform exchange or the like before a component or the like of the power conversion device 20 or the electric motor 30 fails. In this case, the control unit 13 may notify the anomaly of the specific type by, for example, causing LED (Light Emitting Diode to emit light in a light emission mode corresponding to the specific type (for example, an interval of blinking).

### (Information Processing Apparatus)

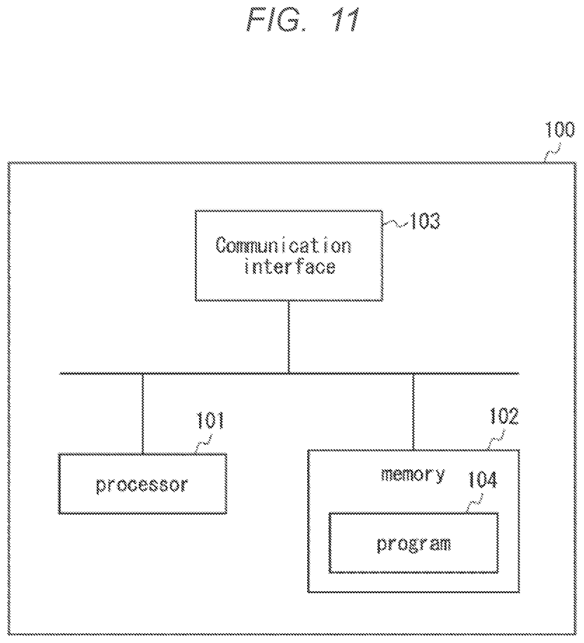

FIG. 11 is a diagram illustrating an example of a configuration of the information processing apparatus 10 according to the embodiment. In the example of FIG. 11, the information processing apparatus 10 includes a processor 101, a memory 102, and a communication interface 103. These units may be connected by a bus or the like. The memory 102 stores at least a part of the program 104. The communication interface 103 includes an interface necessary for communication with other network elements.

When the program 104 is executed by the cooperation of the processor 101 and the memory 102, the computer 100 performs processing of at least a part of the embodiments of the present disclosure. The memory 102 may be of any type suitable for a local technology network. Memory 102 may be, by way of non-limiting example, a non-transitory computer-readable storage medium. Memory 102 may also be implemented using any suitable data storage technology, such as semiconductor-based memory devices, magnetic memory devices and systems, optical memory devices and systems, fixed and removable memory, and the like. Although only one memory 102 is shown in computer 100, there may be several physically different memory modules in computer 100. The processor 101 may be of any type. The processor 101 may include one or more of a general purpose computer, a special purpose computer, a microprocessor, a digital-signal processor (DSP: Digital Signal Processor), and, as non-limiting examples, a processor based on a multi-core processor architecture. The computer 100 may comprise a plurality of processors, such as application specific integrated circuit chips, which are temporally dependent on the clock that synchronizes the main processor.

The program can be stored using various types of non-transitory computer readable media and supplied to a computer. Non-transitory computer readable media includes various types of tangible storage media. Examples of non-transitory computer-readable media include magnetic recording media, magneto-optical recording media, optical disk media, semiconductor memory, and the like. Examples of the magnetic recording medium include a flexible disk, a magnetic tape, and a hard disk drive. The magneto-optical recording medium includes, for example, a magneto-optical disk. Optical disc media include, for example, Blu-ray discs, CD (Compact Disc)-ROM (Read Only Memory), CD-R(Recordable), CD-RW(ReWritable), etc. Semiconductor memories include, for example, solid-state drives, mask ROM, PROM (Programmable ROM), EPROM (Erasable PROM), flash ROM, RAM (random access memory), etc. The program may also be supplied to the computer by various types of transitory computer-readable media. Examples of transitory computer-readable media include electrical signals, optical signals, and electromagnetic waves. The transitory computer readable medium may provide the program to the computer via wired or wireless communication paths, such as electrical wires and optical fibers.

The information processing apparatus 10 may be provided outside the power conversion apparatus 20, for example. In this case, for example, the information processing apparatus 10 may be housed in the housing of the electric motor 30 and configured as an integrated information processing apparatus. The information processing apparatus 10 may be an apparatus included in one housing, but the information processing apparatus 10 of the present disclosure is not limited to this. Each unit of the information processing apparatus 10 may be realized by, for example, cloud computing constituted by one or more computers. Such an information processing apparatus 10 is also included in an example of an “information processing apparatus” of the present disclosure.

Although the invention made by the inventor has been specifically described based on the embodiment, the present invention is not limited to the embodiment already described, and it is needless to say that various modifications can be made without departing from the gist thereof.

What is claimed is:

1. An information processing apparatus comprising:
an acquisition circuit configured to acquire temperature information indicating a transition of temperature in a semiconductor element of a power conversion device for driving an electric motor and current information indicating a transition of a current to the electric motor,
an estimation circuit configured to estimate a system anomaly value indicating a predetermined anomaly in at least one of the power conversion device and the electric motor based on the temperature information and the current information.

2. The information processing apparatus according to claim 1, further comprising:
a control circuit configured to periodically perform an inspection of the power conversion device and the electric motor by controlling the acquisition in the acquisition circuit and the estimation in the estimation circuit.

3. The information processing apparatus according to claim 2,
wherein the control circuit increases a frequency of the inspection when the system anomaly value exceeds a threshold value.

4. The information processing apparatus according to claim 2,
wherein the control circuit outputs anomaly information signal corresponding the predetermined anomaly.

5. The information processing apparatus according to claim 1,
wherein the estimation circuit is configured to estimate a temperature anomaly value and a current anomaly value based on the temperature information and the current information respectively, and
wherein the estimation circuit is configured to estimate the system anomaly value based on a correlation between the temperature anomaly value and the current anomaly value.

6. The information processing apparatus according to claim 5,
wherein the temperature anomaly value is estimated base on the transition of the temperature of the semiconductor element and temperature anomaly likeness information corresponding to each temperature of the semiconductor element.

7. The information processing apparatus according to claim 5,
wherein the current anomaly value is estimated based on the transition of the current to the electric motor and current anomaly likeness information corresponding to each current to the electric motor.

8. The information processing apparatus according to claim 1,
wherein the acquisition circuit further acquires vibration information indicating a transition of vibration in the electric motor.

9. The information processing apparatus according to claim 8,
wherein the estimation circuit is configured to estimate a temperature anomaly value, a current anomaly value and a vibration anomaly value based on the temperature information, the current information and the vibration information respectively, and
wherein the estimation circuit is configured to estimate the system anomaly value based on correlations of the temperature anomaly value, the current anomaly value and the vibration anomaly value.

10. The information processing apparatus according to claim 9,
wherein the vibration anomaly value is estimated based on the transition of the vibration in the electric motor and vibration anomaly likeness information corresponding to each type of vibrations to the electric motor.

11. An information processing method comprising:
acquiring temperature information indicating a transition of temperature in a semiconductor element of a power conversion device for driving an electric motor and current information indicating a transition of a current to the electric motor,
estimating a system anomaly value indicating a predetermined anomaly in at least one of the power conversion device and the electric motor based on the temperature information and the current information.

12. The information processing method according to claim 11, further comprising:
inspecting the power conversion device and the electric motor by controlling the acquisition in the acquisition circuit and the estimation in the estimation circuit.

13. The information processing method according to claim 12, further comprising:
increasing a frequency of the inspection when the system anomaly value exceeds a threshold value.

14. The information processing method according to claim 12, further comprising:
outputting anomaly information signal corresponding the predetermined anomaly.

15. The information processing apparatus according to claim 11,
wherein the estimating includes to estimate a temperature anomaly value and a current anomaly value based on the temperature information and the current information respectively, and
wherein the system anomaly value is estimated based on a correlation between the temperature anomaly value and the current anomaly value.

16. The information processing method according to claim 15,
wherein the temperature anomaly value is estimated base on the transition of the temperature of the semiconductor element and temperature anomaly likeness information corresponding to each temperature of the semiconductor element.

17. The information processing method according to claim 15,
wherein the current anomaly value is estimated based on the transition of the current to the electric motor and current anomaly likeness information corresponding to each current to the electric motor.

18. The information processing method according to claim 1,
wherein the acquiring includes to acquire vibration information a transition of vibration in the electric motor.

19. The information processing method according to claim 18,
wherein the estimating includes to estimate a temperature anomaly value, a current anomaly value and a vibration anomaly value based on the temperature information, the current information and the vibration information respectively, and
wherein the system anomaly value is estimated based on correlations of the temperature anomaly value, the current anomaly value and the vibration anomaly value.

20. The information processing method according to claim 19,
wherein the vibration anomaly value is estimated based on the transition of the vibration in the electric motor and vibration anomaly likeness information corresponding to each type of vibrations to the electric motor.
